(19) United States
(12) Patent Application Publication
(10) Pub. No.: US 2025/0212481 A1
(43) Pub. Date: Jun. 26, 2025

(54) FORKSHEET DEVICE ARCHITECTURE IN STANDARD CELLS

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/390,959

(22) Filed: Dec. 20, 2023

(51) Int. Cl. H01L 29/417; H01L 23/528; H01L 29/06; H01L 29/40; H01L 29/423; H01L 29/66; H01L 29/775; H01L 29/786

(52) U.S. Cl. CPC H10D 64/254; H01L 23/5286; H10D 30/014; H10D 30/43; H10D 30/6735; H10D 30/6757; H10D 62/121; H10D 64/01

(57) ABSTRACT

Disclosed are forksheet (FS) cells whose shared gate and source/drains (S/Ds) are split by a dielectric wall. The cell include backside contacts—a backside gate strap contact, a backside passthrough contact, and direct backside contacts (BSCs). The backside contacts overcome the gate obstacle problem and the contact obstacle problem of conventional FS cells.

### BACKGROUND OF THE DISCLOSURE

### 1. Field of the Disclosure

This disclosure relates generally to semiconductor devices, and more specifically, but not exclusively, to a forksheet device architecture in standard cells, and fabrication techniques thereof. For example, source/drain and gate contact solutions may be provided to enable forksheet device architecture in standard cells for backside power distribution network (BSPDN) implementation.

### 2. Description of the Related Art

Integrated circuit technology has achieved great strides in advancing computing power through miniaturization components such as semiconductor transistors. Semiconductors have progressed from bulk substrates and planar CMOS, FinFETs, nanowires or nanoribbons (also called nanosheets), to nanowire or nanoribbon 3D stacking. Semiconductor technologies have largely been based on silicon. However, fabrication of transistors based on silicon may be problematic when it comes to further reduction in scaling, e.g., to few nanometers. Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary forksheet (FS) cell is disclosed. The FS cell may comprise a shared gate and a plurality of nanosheets within the shared gate. The FS cell may also comprise a dielectric wall (DW) splitting the shared gate into first and second shared gate portions. The DW may also split each nanosheet into first and second nanosheet portions. The FS cell may further comprise a backside gate strap contact on a backside of the shared gate and on a backside of the DW. The backside gate strap contact may be in physical contact with lower surfaces of both the first and second shared gate portions of the shared gate. The first and second shared gate portions of the shared gate may be electrically coupled to each other through the backside gate strap contact. The first nanosheet portion forms a first channel when a first turn-on signal is applied to the shared gate and is prohibited from being formed when a second turn-on signal is applied to the shared gate. The second nanosheet portion forms a second channel when the second turn-on signal is applied to the shared gate and is prohibited from being formed when the first turn-on signal is applied to the shared gate.

A method of fabricating a forksheet (FS) cell is disclosed. The method may comprise forming a shared gate and forming a plurality of nanosheets within the shared gate. The method may also comprise forming a dielectric wall (DW) splitting the shared gate into first and second shared gate portions. The DW may also split each nanosheet into first and second nanosheet portions. The method may further comprise forming a backside gate strap contact on a backside of the shared gate and on a backside of the DW. The backside gate strap contact may be in physical contact with lower surfaces of both the first and second shared gate portions of the shared gate. The first and second shared gate portions of the shared gate may be electrically coupled to each other through the backside gate strap contact. The first nanosheet portion forms a first channel when a first turn-on signal is applied to the shared gate and is prohibited from being formed when a second turn-on signal is applied to the shared gate. The second nanosheet portion forms a second channel when the second turn-on signal is applied to the shared gate and is prohibited from being formed when the first turn-on signal is applied to the shared gate.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a conventional nanosheet field effect transistor (FET) prior to forming the source/drain epitaxials.

FIG. 1B illustrates shared gate obstacle issues associated with the conventional nanosheet FET.

FIG. 1C illustrates output diffusion contact obstacle issues associated with the conventional nanosheet FET.

FIG. 2A illustrates a top view of a conventional cell with nanosheet FETs.

FIG. 2B illustrates a view of a conventional cell with nanosheet FETs showing deep trench vias.

FIG. 3A illustrates a cross sectional view of the conventional cell along a shared gate region showing an example of a gate obstacle problem.

FIGS. 3B, 3C and 3D illustrate cross sectional views of the conventional cell along epi regions showing examples of contact obstacle problems.

FIG. 4 illustrates a top view of a proposed cell with nanosheet FETs in accordance with one or more aspects of the disclosure.

FIG. 5A illustrates a cross sectional view of the proposed cell along a shared gate region that addresses the gate obstacle problem in accordance with one or more aspects of the disclosure.

FIGS. 5B and 5C illustrate cross sectional views of the proposed cell along epi regions that address the contact obstacle problems in accordance with one or more aspects of the disclosure.

FIGS. 6-7C illustrate flow charts of example methods of fabricating a forksheet cell in accordance with one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are forksheet (FS) cells and methods for fabricating the same. In an aspect, the FS cell may comprise a shared gate and a plurality of nanosheets within the shared gate. The FS cell may also comprise a dielectric wall (DW) splitting the shared gate into first and second shared gate portions. The DW may also split each nanosheet into first and second nanosheet portions. The FS cell may further comprise a backside gate strap contact on a backside of the shared gate and on a backside of the DW. The backside gate strap contact may be in physical contact with lower surfaces of both the first and second shared gate portions of the shared gate. The first and second shared gate portions of the shared gate may be electrically coupled to each other through the backside gate strap contact. The first nanosheet portions of the plurality of nanosheets may form a first channel when a first turn-on signal is applied to the shared gate. The first channel may be prohibited from being formed when a second turn-on signal is applied to the shared gate. Conversely, the second nanosheet portions of the plurality of nanosheets may form a second channel when the second turn-on signal is applied to the shared gate. The second channel may be prohibited from being formed when the first turn-on signal is applied to the shared gate.

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Forksheet (FS) architecture includes a dielectric wall (DW) between the N field effect transistor (NFET) and PFET. The dielectric wall enables space compaction by blocking epitaxial-to-epitaxial (epi-to-epi) shorting. The dielectric wall is formed early in the ‘fin module’ prior to shallow trench isolation (STI).

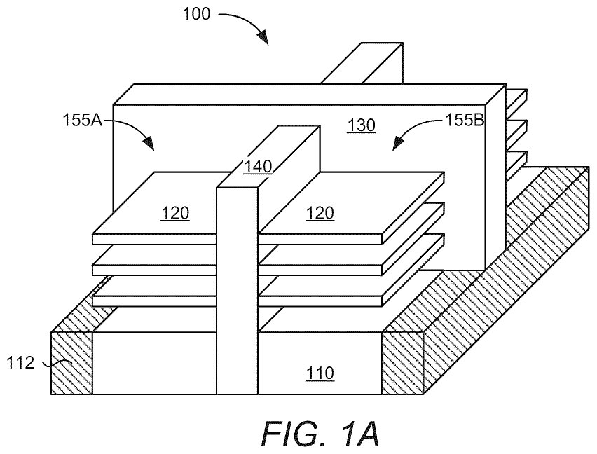

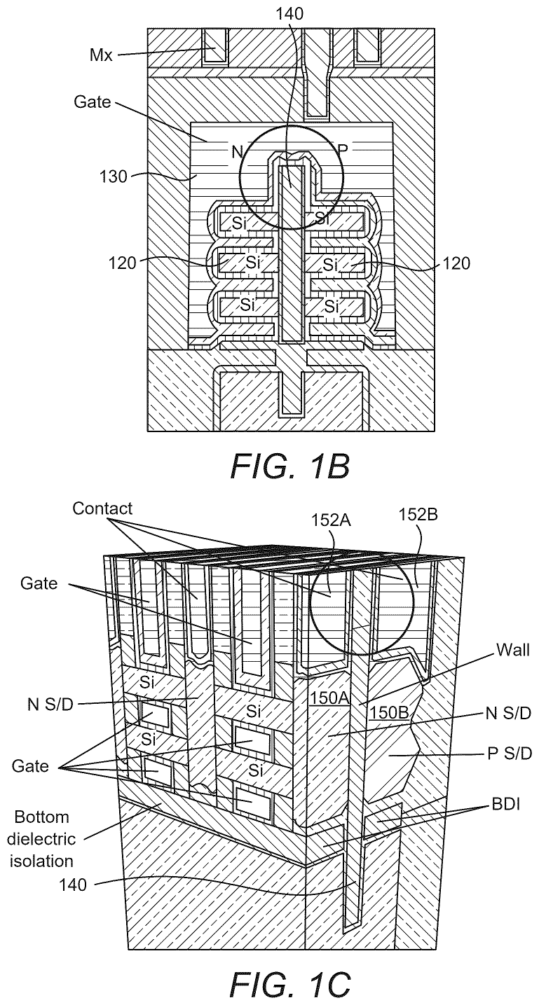

FIG. 1A illustrates a conventional nanosheet field effect transistor (FET) 100 prior to forming the source/drain epi-regions. The nanosheet FET 100 is built upon a silicon substrate 110 and comprises a set of three nanosheets that extend through a gate 130 (e.g., a gate-all-around (GAA) gate). A dielectric wall (DW) 140 splits the substrate 110, and the nanosheets to two regions—a first epitaxial (epi) region 155A on the left side of the dielectric wall 140, and a second epi region 155B on the right side of the dielectric wall 140. The DW 140 completely separates the nanosheets 120 into left and right portions. The dielectric wall 140 also goes through the gate 130. However, since the gate 130 is taller than the dielectric wall 140, the gate 130 is electrically continuous on both left and right of the dielectric wall 140. The gate 130 is isolated from the substrate 110 by oxide isolation regions 112.

While not shown, the left and right portions of the nanosheets 120 that extend from the channel areas (of the gate 130) will be recessed and/or etched off and epi regions will be grown from the nanosheets (or channel ribbons) later on in the process to form the transistor structure. In the first epi region 155A, a first S/D is formed. For example, the first S/D (e.g., one of N and P type) is formed through epitaxial growth. In the second epi region, a second S/D is formed. For example, the second S/D (e.g., other of N and P type) is formed through epitaxial growth.

However, the nanosheets 120 remain within the gate 130. Left and right portions of the nanosheets 120 are physically divided by the dielectric wall 140 within the gate 130. The nanosheets 120 are the channels by which the charge carrier travels through the gate 130 from/to the first and second S/Ds. It may be assumed that similar first and second S/Ds are also formed on the rear side of the gate 130.

The dielectric wall should be kept tall enough to prevent epi-to-epi shorts. That is, the dielectric wall 140 should be tall enough to prevent the first and second S/Ds (formed in the first and second epi regions 155A, 155B) from shorting. However, there are two challenges created by this with this general forksheet structure. First, the DW 140 creates a physical obstacle for a shared gate 130 as seen in FIG. 1B. This obstacle increases the gate resistance and also provides a yield challenge (i.e., gate opens). If the gate height is increased to contain the resistance, it increases the parasitic gate to contact capacitance across the chip. If the DW 140 is lowered to reduce the gate height need, then there will be a risk of epi to epi shorting in the diffusion region. In the prior art, a separate frontside gate jumper has been proposed to avoid the gate resistance challenge caused by the DW in the shared gate. However, this adds back to the gate to contact capacitance because the frontside gate jumper spans the majority of the shared gate. The second problem is that the DW 140 creates an obstacle for the MOL (output) diffusion contacts 152A, 152B for contacting the first and second source/drains (S/Ds) as seen in FIG. 1C. If the DW 140 in the diffusion region (occupied by the first and second S/Ds 150A, 150B) is etched down to lower the obstacle, this simultaneously etches the gate sidewall spacers which increases the gate to contact yield risk.

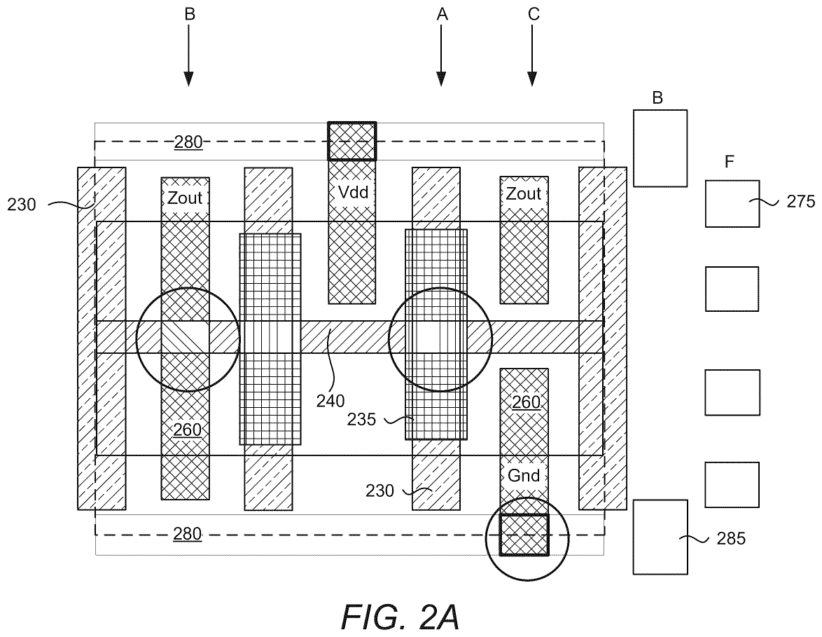

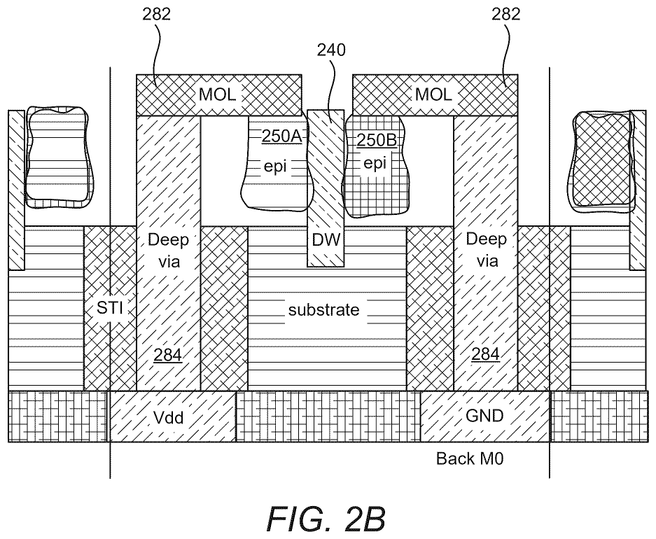

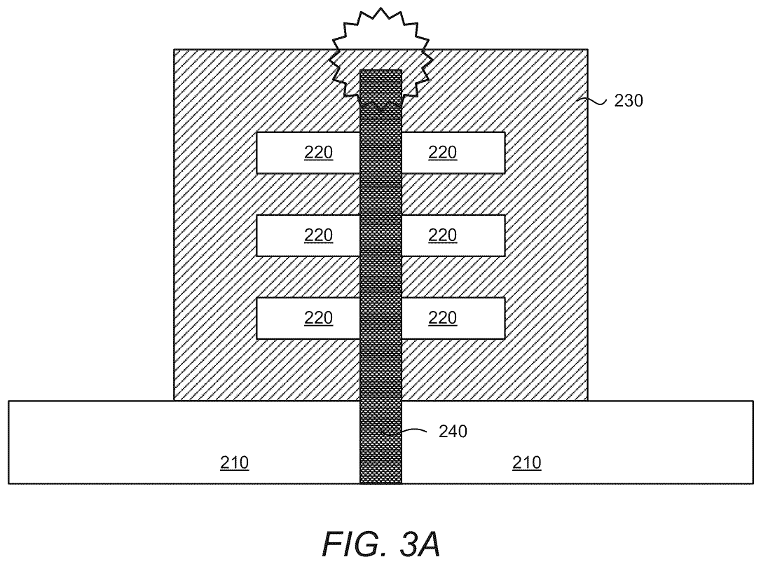

FIG. 2A is a top view of a logic cell 200 based on the forksheet architecture with DW that illustrates some of the problems outlined above. The cell 200 is based on backside power delivery network (PDN) and includes backside Vdd and GND metal lines (not shown) that run horizontally. Frontside metals 275, frontside lines 270 and backside metals 285 provide the Vdd and GND potentials to the cell 200. The Vdd and GND signals are transferred from the backside PDN to the frontside diffusion contacts through a deep vertical trench via 284 that also runs horizontally along the cell boundary as seen in FIG. 2B. The deep vertical trench vias 284 consume additional space and prevent aggressive cell height compaction. Metal gates 230 running vertically are laid out within the upper and lower boundaries of the logic cell. Dielectric wall 240 runs horizontally and is placed at the midpoint of the logic cell. Frontside contacts 260 are formed over the diffusion (epitaxial) regions in the regions between the metal gates 230. Since the DW 240 has created a resistive obstacle for the shared gate 230, a gate jumper 235 (see FIG. 2A) has been included in the logic cell architecture to recover the continuity that the DW 240 breaks.

The areas designated with circles in FIG. 2A highlight the challenges or obstacles with this baseline forksheet logic cell topology. The obstacles may be categorized into the following sectors which were introduced earlier:
1. Gate obstacle problem—dielectric wall (DW) creates an obstacle for forming a shared gate, resulting in gate resistance and yield pinch points.
2. Contact obstacle problem—DW creates an obstacle for middle-of-line (MOL) contact which forms the output connection in the logic cells.
3. The Deep via method of bringing the Vdd and GND from BSPDN to the front MOL contacts consumes space that prevents aggressive cell height scaling.

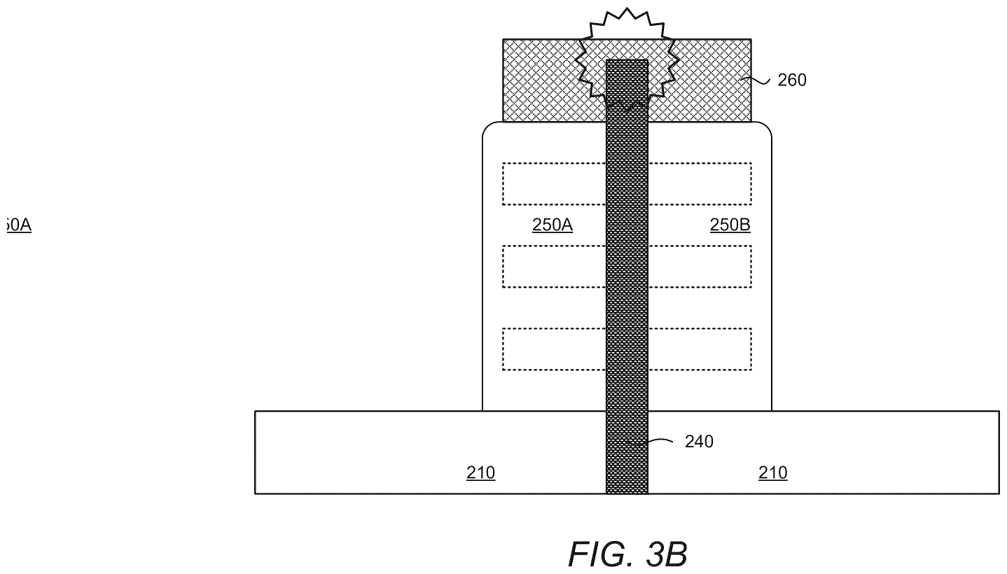

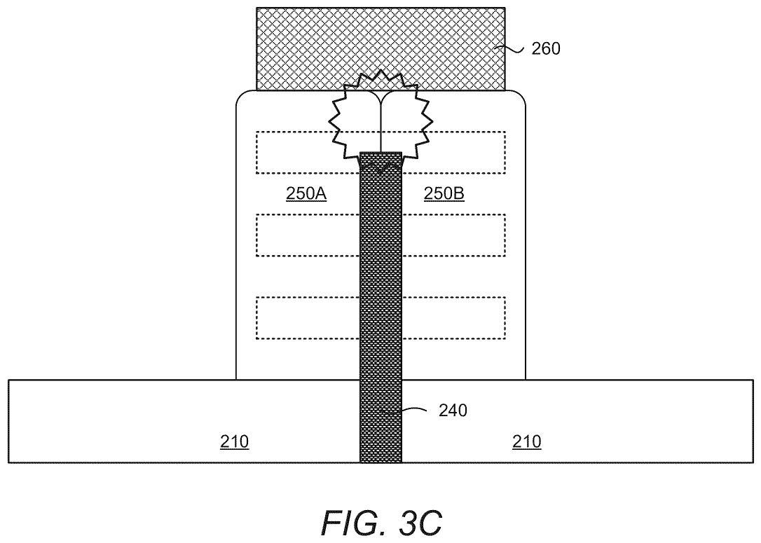

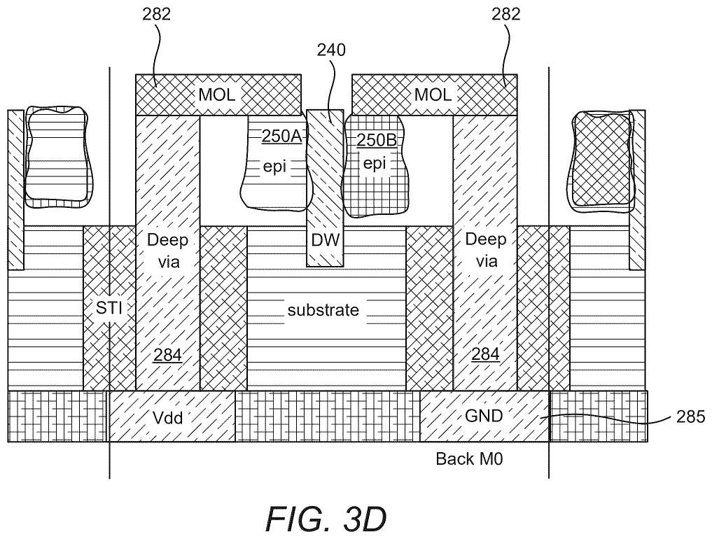

Note that in FIG. 2A, there are vertical arrows labeled ‘A’, ‘B’ and ‘C’. FIG. 3A illustrates a cross section along the Y direction along the arrow labeled ‘A’ of FIG. 2A. This is an example of the gate obstacle problem described above. As seen in FIG. 3A, the cell includes a shared gate 230, nanosheets 420 within the shared gate 230, and silicon substrate 210. The DW 240 pinches the shared gate 230 at the upper portion thereof as highlighted by the multi-pointed star. The technical disadvantages of the pinch point are that it will cause an undesirable increase in resistance in the shared gate 230, or if extreme enough, will create a disconnect in the shared gate 230 that leads to an “opens mode” failure which represents yield loss. The height of the shared gate 230 can be raised to contain the resistance and reduce exposure to yield loss. However, the problem with raising the gate height is that it will increase the parasitic gate to contact capacitance across the entire design A gate jumper 235 on top of the DW 140 has been proposed to address the pinch point. However, a technical disadvantage of installing the gate jumper 235 is that it requires extra process complication along with cost implications, yet still increases the parasitic contact to gate capacitance (similar to raising the effect of raising the gate height).

FIG. 3B illustrates a cross section along the Y direction along the arrow labeled ‘B’ of FIG. 2A. This is an example of the contact 260 obstacle described above. The cut illustrates the diffusion region where epitaxial S/Ds are formed. In FIG. 3B, the DW 240 splits the first (e.g., N) and second (e.g., P) S/Ds 250A, 250B. Recall that a purpose of the DW 240 is to prevent the first and second S/Ds 250A, 250B from being shorted to each other. This can be accomplished by making the DW 240 of sufficient height. However, if the height is too great, a technical disadvantage is that it then can become an obstacle for MOL output connection (as highlighted by the multi-pointed star). In FIG. 3B, this can become an obstacle in forming the frontside contact.

To address this issue, the DW 240 can be initially formed to be of smaller height. However, this is also a problem as shown in FIG. 3C (highlighted by the multi-pointed star), which also illustrates a cross section along the Y direction along the arrow labeled ‘B’ of FIG. 2A. During the process of forming spacers (prior to forming the S/Ds), the DW 240 can also be etched resulting in reduced height. When the height is reduced too much, a technical disadvantage is that the first and second S/Ds 250A, 250B can be shorted.

FIG. 3D illustrates a cross section along the Y direction along the arrow labeled ‘C’ of FIG. 2A. Here, on the frontside (topside) of the cell 200, tops of each of the first and second S/Ds 250A, 250B are in contact with front MOL contact 282. These are in turn in contact with corresponding deep vias 284. On the backside of the cell 200, the BMO power rails are in contact with the respective deep vias 284.

To address these and other issues of baseline forksheet cell with DW, it is proposed to use backside contacts. Using this approach, both the gate obstacle and contact obstacle problems can be addressed.
1. Backside gate strap for shared gate formed on the backside—a technical advantage can be lowering of parasitic capacitance.
2. MOL output (N/P passthrough) formed on the backside—a technical advantage can be overcoming the DW obstacle that exists on the front, then it gets picked up from the frontside from either side of the N or P for flexible routing.
3. Direct backside contact (BSC) Vdd/GND connections with forksheet (instead of deep via connectors to the back grid)—technical advantages can be that direct BSC can be crucial for controlling (and reducing) resistance and enable cell height reduction.

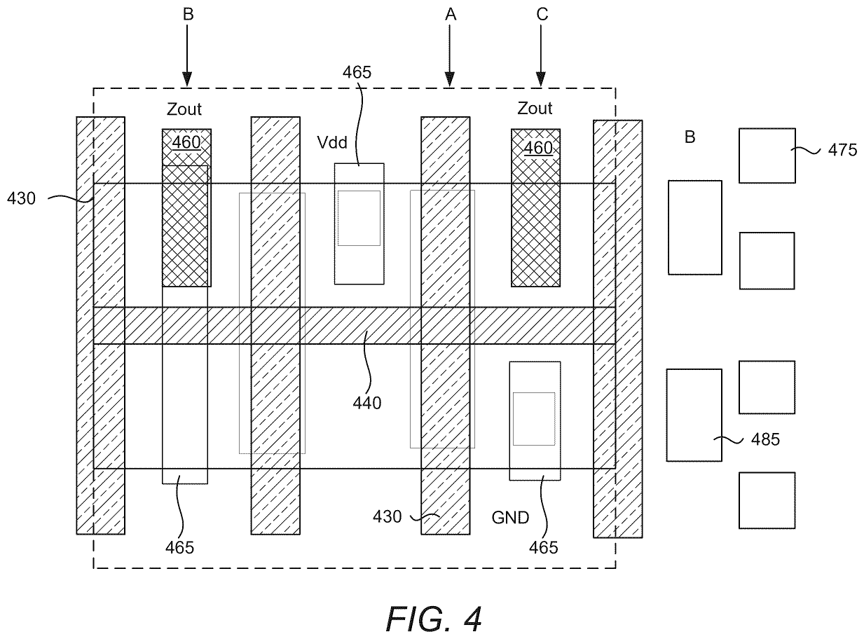

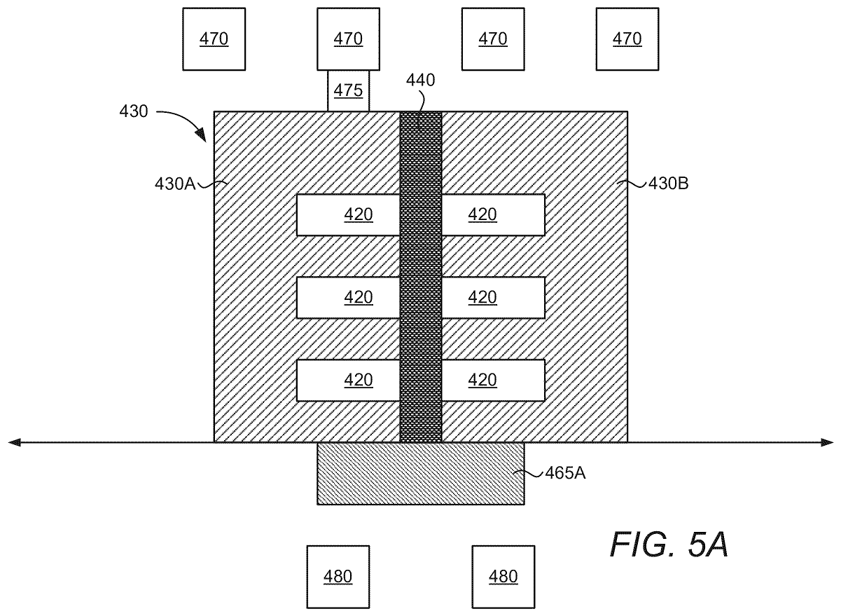

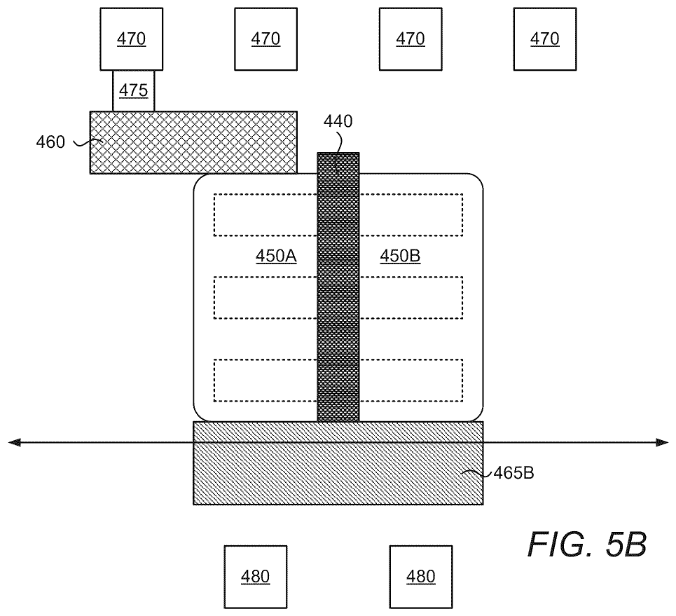

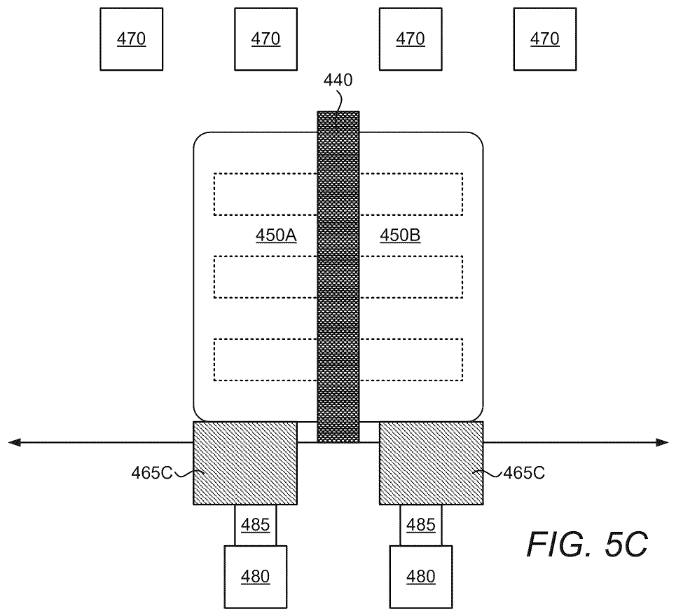

FIG. 4 illustrates a top view of a proposed cell 400 with nanosheet FETs in accordance with one or more aspects of the disclosure. Cell 400 may also be referred to as a forksheet (FS) cell. Metal gates 430 running vertically may be laid out spaced apart from each other. In this instance, the metal gates 430 may also be referred to as shared gates 430 in that the gates 430 may be shared by both first and second S/Ds 450A, 450B (e.g., as seen in FIGS. 5B and 5C). Frontside contacts 460 and backside contacts 465 may be electrically coupled with the first and second S/Ds 450A, 450B in the epitaxial regions. The dielectric wall (DW) 440 may be horizontally placed to split the gates 430 and/or the shared gates 435. As will be shown in FIGS. 5A, 5B and 5C, the use of the backside contacts 465 can address both the gate obstacle and the contact obstacle problems.

In FIG. 4, there are also vertical arrows labeled ‘A’, ‘B’ and ‘C’. FIG. 5A illustrates a cross section along the Y direction along the arrow labeled ‘A” of FIG. 4. FIG. 5A illustrates an example of how the gate obstacle problem may be addressed with a backside gate strap contact. As seen, the cell 400 may include a shared gate 430 and a plurality of nanosheets 420 within the shared gate 430. A dielectric wall (DW) 440 may split the shared gate 430 into first (e.g., left) and second (e.g., right) shared gate portions. Note that the heights of the DW 440 and the shared gate 430 may be the same. For example, lower surfaces of the DW 440 and of the shared gate 430 may be aligned. Alternatively or in addition thereto, upper surfaces of the DW 440 and of the shared gate 430 may be aligned. In this way, the height of the shared gate 430 may be reduced, which is technically advantageous.

The DW 440 may also split each nanosheet 420 into first and second nanosheet portions. The first nanosheet portion may form a first channel when a first turn-on signal is applied to the shared gate and may be prohibited from being formed when a second turn-on signal is applied to the shared gate. The second nanosheet portion may form a second channel when the second turn-on signal is applied to the shared gate and may be prohibited from being formed when the first turn-on signal is applied to the shared gate.

As the name implies, the shared gate 430 may be shared by both the first and second nanosheet portions of the plurality of nanosheets 420. That is, the first and second shared gate portions may be electrically coupled with each other. This may be accomplished through a backside gate strap or backside contact (BSC) 465 formed on the backside of the shared gate 430. In this instance, the backside gate strap accomplishing this purpose may be the backside gate strap contact 465A. Note that the backside gate strap contact 465A may also be on the backside of the DW (440). The backside gate strap contact 465A may be in physical contact with the lower surfaces of both the first and second shared gate portions of the shared gate 430. That is, the backside gate strap contact 465A may be in physical contact with the lower surface of the shared gate 430. In this way, the first and second shared gate portions 430A, 430B of the shared gate 430 may be electrically coupled to each other through the backside gate strap contact 465A. The backside gate strap contact 465A can address the resistance and parasitic capacitance issues without increasing the height of the shared gate 430. Note that the backside gate strap contact 465A may also be in physical contact with the lower surface of the DW 440 in the gate area. In FIG. 5A (and in FIGS. 5B and 5C), the left-right arrow represents the lower surface level of the shared gate 430.

A frontside metal—e.g., FM0—475 may be electrically coupled to the frontside of the shared gate 430. For example, the frontside metal 475 may be in direct contact with an upper surface of the first shared gate portion 430A (shown in FIG. 5A) or with an upper surface the second shared gate portion 430B (not shown in FIG. 5A) of the shared gate 430. The frontside metal 475 may be configured to apply the first and second turn-on signals to the shared gate 430.

One or more frontside lines 470 may be formed on the frontside of the shared gate 430 above the frontside metal 475. At least one frontside line 470 may be electrically coupled (e.g., in contact) to an upper surface of the frontside metal 475. The at least one frontside line 470 may be configured to provide the first and second turn-on signals to the frontside metal 475.

There can also be one or more backside lines 480 below the backside of the shared gate 430. For example, the one or more backside lines 480 may be formed below the backside gate strap contact 465A.

FIG. 5B illustrates a cross section along the Y direction along the arrow labeled ‘B’ of FIG. 4. FIG. 5B illustrates an example of a contact obstacle problem may be addressed. Again, this is the diffusion region adjacent to the shared gate 430 where epitaxial S/Ds may be formed. In FIG. 5B, the DW 440 may split the first (e.g., N) and second (e.g., P) S/Ds 450A, 450B. In this way, the first and second S/Ds 450A, 450B may be prevented from connecting to each other. In an aspect, when the first turn-on signal is applied to the shared gate 430, the first S/D 450A may be conductively coupled respectively to the first and channel of the first nanosheet portions of the plurality of nanosheets 420. Alternatively or in addition thereto, when the second turn-on signal is applied to the shared gate 430, the second S/D 450B may be conductively coupled respectively to the second channel of the second nanosheet portions of the plurality of nanosheets 420.

In FIG. 5B, the backside contact 465 configured to address the contact obstacle problem may be a backside passthrough contact 465B formed on backsides of the first S/D 450A, the second S/D 450B, and the DW 440. In an aspect, the backside passthrough contact 465B in physical contact with lower surfaces of both the first S/D 450A and the second S/D 450B. The first S/D 450A and the second S/D 450B may be electrically coupled to each other through the backside passthrough contact 465B. The backside passthrough contact 465B in physical contact with the lower surface of the DW 440 in the S/D area.

In an aspect, a lower surface of the DW 440 and the lower surfaces of the first and second S/Ds 450A, 450B may be aligned. Alternatively or in addition thereto, an upper surface of the DW 440 may be above upper surfaces of the first and second S/Ds 450A, 450B. In another aspect, the lower surfaces of the DW 440 and/or of the lower surfaces of the first and second S/Ds 450A, 450B may be above the lower surface of the shared gate 430 (above the left-right arrow representing the lower surface level of the shared gate 430).

A frontside contact (FSC) 460 may be electrically coupled to the frontside of the first S/D 450A (shown in FIG. 5B) or to the frontside of the second S/D 450B (not shown). For example, the frontside contact 460 may be in direct contact with the upper surface of the first S/D (450A) or the upper surface of the second S/D 450B. The frontside contact 460 may be configured to apply a signal, power, or ground to the first and the second S/Ds 450A, 450B.

A frontside metal—e.g., FM0—475 may be electrically coupled to the frontside of the frontside contact 460. For example, the frontside metal 475 may be in direct contact with an upper surface of the frontside contact 460.

One or more frontside lines 470 may be formed on the frontside of the first and/or second S/Ds 450A, 450B above the frontside metal 475. At least one frontside line 470 may be electrically coupled (e.g., in contact) to an upper surface of the frontside metal 475. The at least one frontside line 470 may be configured to provide the power, signal, or ground to the frontside metal 475.

There can also be one or more backside lines 480 below the backside of the first and second S/Ds 450A, 450B. For example, the one or more backside lines 480 may be formed below the backside passthrough contact 465B.

FIG. 5C illustrates a cross section along the Y direction along the arrow labeled ‘C’ of FIG. 4. FIG. 5C illustrates the general connection scheme for direct backside power contacts to this forksheet topology. Again, this is an area adjacent to the shared gate 430 where epitaxial S/Ds may be formed. In FIG. 5C, the DW 440 may split the first and second S/Ds 450A, 450B to prevent the first and second S/Ds 450A, 450B from being shorted to each other. When the first turn-on signal is applied to the shared gate 430, the first S/D 450A may be conductively coupled respectively to the first and channel of the first nanosheet portions of the plurality of nanosheets 420. Alternatively or in addition thereto, when the second turn-on signal is applied to the shared gate 430, the second S/D 450B may be conductively coupled respectively to the second channel of the second nanosheet portions of the plurality of nanosheets 420.

In FIG. 5C, The first direct BSC 465C may be formed on a backside of the first S/D 450A. For example, the first direct BSC 465C may be in physical contact with a lower surface the first S/D 450A. As such, the first direct BSC 465C may be electrically coupled with the first S/D 450A. The second direct BSC 465C may be formed on a backside of the second S/D 450B. For example, the second direct BSC 465C may be in physical contact with a lower surface the second S/D 450B. As such, the second direct BSC 465C may be electrically coupled with the second S/D 450B.

In an aspect, a lower surface of the DW 440 may be lower than the lower surfaces of the first and second S/Ds 450A, 450B. Alternatively or in addition thereto, an upper surface of the DW 440 may be above upper surfaces of the first and second S/Ds 450A, 450B. In another aspect, the surfaces of the first and second S/Ds 450A, 450B may be above the lower surface of the shared gate 430 (above the left-right arrow representing the lower surface level of the shared gate 430). Alternatively or in addition thereto, the lower surface of the DW 440 may be even with the lower surface of the shared gate 430.

A first backside metal 485 may be electrically coupled with the first direct BSC 465C. For example, the first backside metal 485 may be in contact with a lower surface of the first direct BSC 465C. As such, the first backside metal 485 may be electrically coupled to the first S/D 450A through the first direct BSC 465C. A second backside metal 485 may be electrically coupled with the second direct BSC 465C. For example, the second backside metal 485 may be in contact with a lower surface of the second direct BSC 465C. As such, the second backside metal 485 may be electrically coupled to the second S/D 450B through the second direct BSC 465C.

A first backside line 470 may be electrically coupled with the first backside metal 485. For example, the first backside line 470 may be in contact with the first backside metal 485. The first backside line 470 may provide a Vdd or a ground voltage to the first S/D 450A through the first backside metal 485 and the first direct BSC 465C. Alternatively or in addition thereto, a second backside line 470 may be electrically coupled with the second backside metal 485. For example, the second backside line 470 may be in contact with the second backside metal 485. The second backside line 470 may provide a Vdd or a ground voltage to the second S/D 450B through the second backside metal 485 and the second direct BSC 465C.

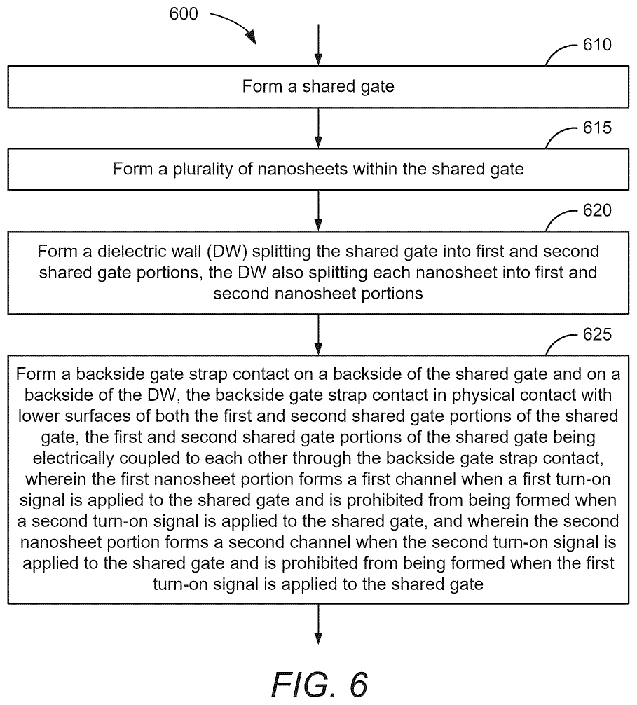

FIG. 6 illustrates a flow chart of an example method 600 of fabricating a forksheet (FS) cell, such as the cell 400 in accordance with one or more aspects of the disclosure. In block 610, a shared gate may be formed, and in block 615, a plurality of nanosheets 420 may be formed within the shared gate 430.

In block 620, a dielectric wall (DW) 440 may be formed to split the shared gate 430 into first and second shared gate portions. The DW 440 may also split each nanosheet 420 into first and second nanosheet portions.

In block 625, a backside gate strap contact 465A may be formed on a backside of the shared gate 430 and on a backside of the DW 440. The backside gate strap contact 465A may be in physical contact with lower surfaces of both the first and second shared gate portions of the shared gate 430. The first and second shared gate portions of the shared gate 430 may be electrically coupled to each other through the backside gate strap contact 465A. The first nanosheet portions of the plurality of nanosheets 420 may form a first channel when a first turn-on signal is applied to the shared gate 430, and may be prohibited from being formed when a second turn-on signal is applied to the shared gate 430. The second nanosheet portions of the plurality of nanosheets 420 may form a second channel when the second turn-on signal is applied to the shared gate 430, and may be prohibited from being formed when the first turn-on signal is applied to the shared gate 430.

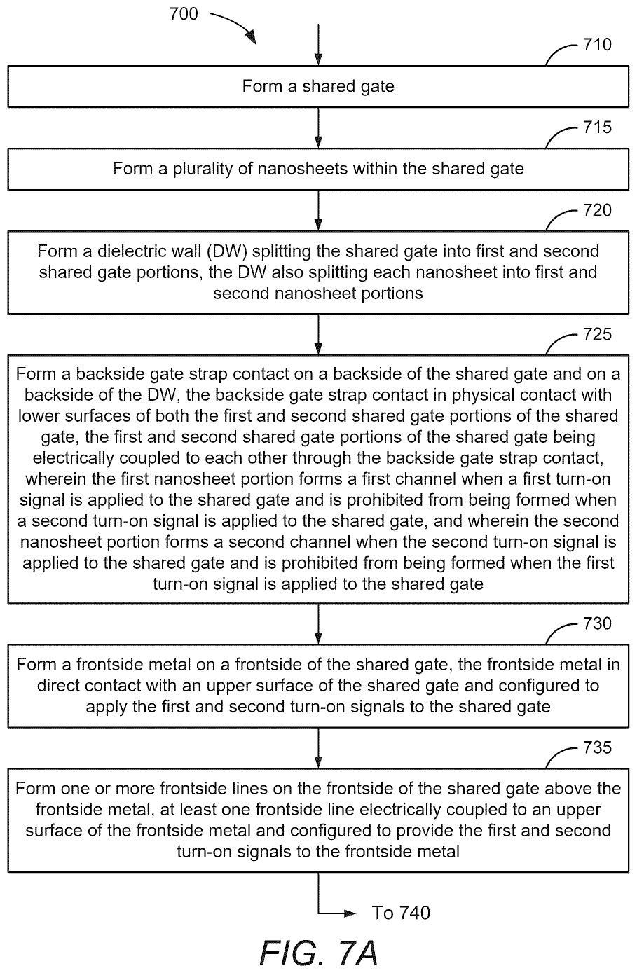

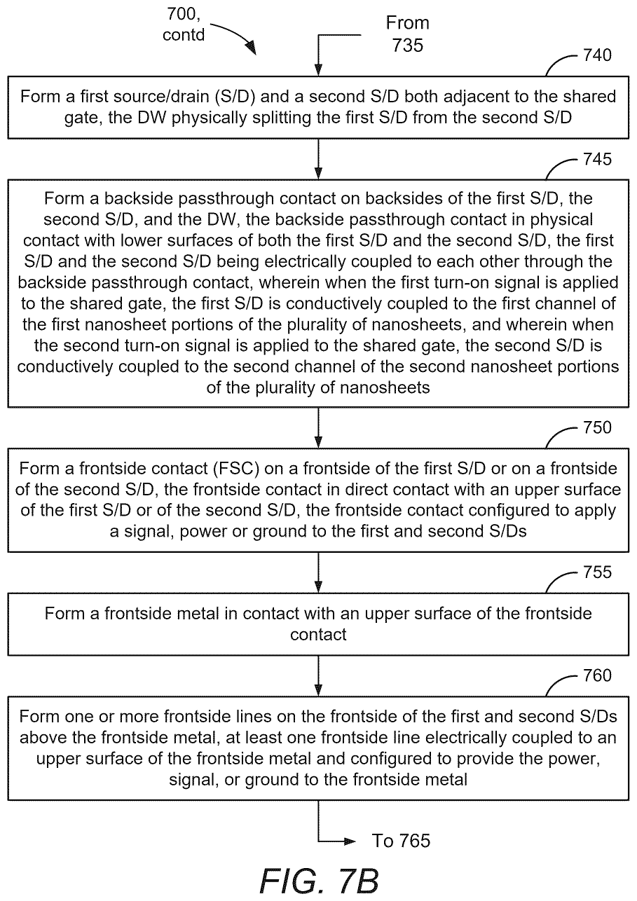

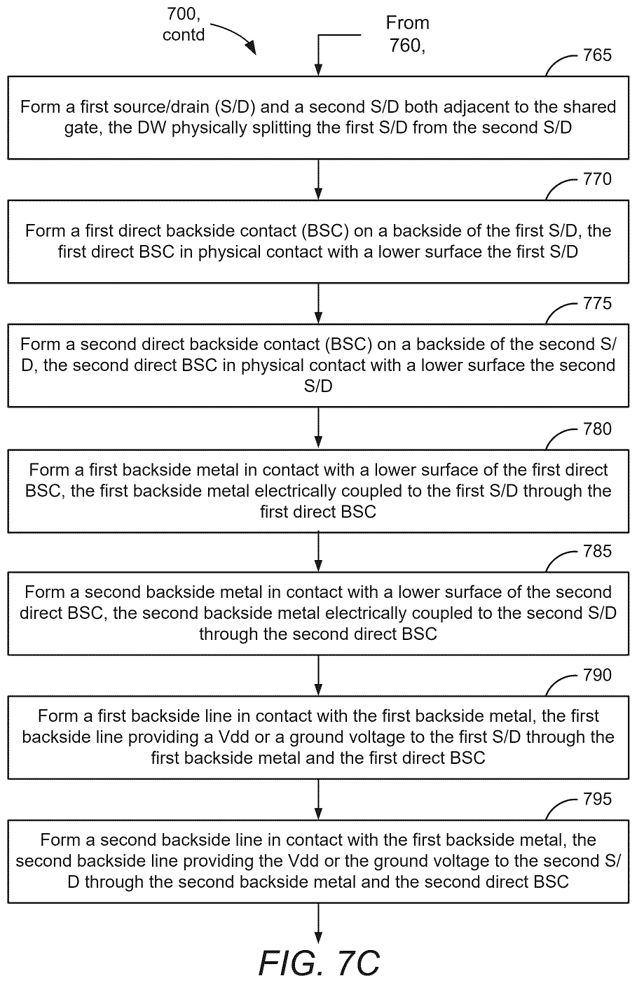

FIGS. 7A, 7B and 7C illustrate a flow chart of an example method 700 of fabricating a forksheet (FS) cell, such as the cell 400 in accordance with one or more aspects of the disclosure. In an aspect, the method 700 may be viewed as a more detailed version of the method 600 to fabricate a FS cell.

Blocks 710, 715, 720 and 725 may be similar to blocks 610, 615, 620 and 625. Therefore, descriptions of blocks 710, 715, 720 and 725 will be omitted for sake of conciseness. Blocks 710, 715, 720 and 725 (and thus blocks 610, 615, 620 and 625) may correspond to FIG. 5A in which the gate obstacle problem is addressed.

In block 730, a frontside metal 475 may be formed on a frontside of the shared gate 430. The frontside metal 475 may be in direct contact with an upper surface of the shared gate 430 and may be configured to apply the first and second turn-on signals to the shared gate 430.

In block 735, one or more frontside lines 470 may be formed on the frontside of the shared gate 430 above the frontside metal 475. At least one frontside line 470 may be electrically coupled to an upper surface of the frontside metal 475 and may be configured to provide the first and second turn-on signals to the frontside metal 475. Blocks 730 and 735 may also correspond to FIG. 5A in which the gate obstacle problem is addressed.

In block 740, a first source/drain (S/D) 450A and a second S/D 450B may be formed both adjacent to the shared gate 430. The DW 440 may physically split the first S/D 450A from the second S/D 450B.

In block 745, a backside passthrough contact 465B may be formed on backsides of the first S/D 450A, the second S/D 450B, and the DW 440. The backside passthrough contact 465B may be in physical contact with lower surfaces of both the first S/D 450A and the second S/D 450B. The first S/D 450A and the second S/D 450B may be electrically coupled to each other through the backside passthrough contact 465B. When the turn-on signal is applied to the shared gate 430, the first S/D 450A and the second S/D 450B may be conductively coupled respectively to the first and second channels of the first and second nanosheet portions of the plurality of nanosheets 420.

In block 750, a frontside contact (FSC) 460 may be formed on a frontside of the first S/D 450A or on a frontside of the second S/D 450B. The frontside contact 460 may be in direct contact with an upper surface of the first S/D 450A or an upper surface of the second S/D 450B. The frontside contact 460 may be configured to apply a signal, power or ground to the first and second S/Ds 450A, 450B.

In block 755, a frontside metal 475 may be formed to be in contact with an upper surface of the frontside contact 460.

In block 760, one or more frontside lines 470 may be formed on the frontside of the first and second S/Ds 450A, 450B above the frontside metal 475. At least one frontside line 470 may be electrically coupled to an upper surface of the frontside metal 475 and may be configured to provide the power, signal, or ground to the frontside metal 475. Blocks 740-760 may correspond to FIG. 5B in which an instance of the contact obstacle problem is addressed.

In block 765, a first source/drain (S/D) 450A and a second S/D 450B may be formed both adjacent to the shared gate 430. The DW 440 may physically split the first S/D 450A from the second S/D 450B. Block 765 is similar to block 740, except that block 760 corresponds to FIG. 5C.

In block 770, a first direct backside contact (BSC) 465C may be formed on a backside of the first S/D 450A. The first direct BSC 465C may be in physical contact with a lower surface the first S/D 450A.

In block 775, a second direct BSC 465C may be formed on a backside of the second S/D 450B. The second direct BSC 465C may be in physical contact with a lower surface the second S/D 450B. When the turn-on signal is applied to the shared gate 430, the first S/D 450A and the second S/D 450B may be conductively coupled respectively to the first and second channels of the first and second nanosheet portions of the plurality of nanosheets 420.

In block 780, a first backside metal 485 may be formed to be in contact with a lower surface of the first direct BSC 465C. The first backside metal 485 may be electrically coupled to the first S/D 450A through the first direct BSC 465C.

In block 785, a second backside metal 485 may be formed to be in contact with a lower surface of the second direct BSC 465C. The second backside metal 485 may be electrically coupled to the second S/D 450B through the second direct BSC 465C.

In block 790, a first backside line 470 may be formed to be in contact with the first backside metal 485. The first backside line 470 may provide a Vdd or a ground voltage to the first S/D 450A through the first backside metal 485 and the first direct BSC 465C.

In block 795, a second backside line 470 may be formed to be in contact with the second backside metal 485. The second backside line 470 may provide a Vdd or a ground voltage to the second S/D 450B through the second backside metal 485 and the second direct BSC 465C.

The following should be noted regarding the flow indicated in FIGS. 6-7C. Unless otherwise indicated, the flow of blocks do not necessarily limit the ordering in which the blocks may be performed. In otherwise, the blocks may be performed in any order that is logical.

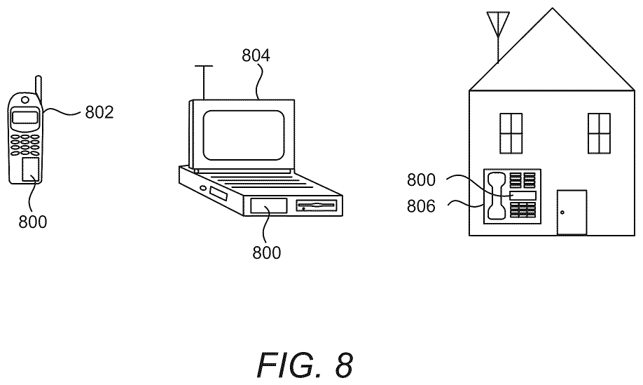

FIG. 8 illustrates various electronic devices 800 that may be integrated with any of the aforementioned forksheet devices in accordance with various aspects of the disclosure. For example, a mobile phone device 802, a laptop computer device 804, and a fixed location terminal device 806 may each be considered generally user equipment (UE) and may include one or more cells (e.g., cells 400) as described herein. The devices 802, 804, 806 illustrated in FIG. 8 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A forksheet (FS) cell, comprising: a shared gate; a plurality of nanosheets within the shared gate; a dielectric wall (DW) splitting the shared gate into first and second shared gate portions, the DW also splitting each nanosheet into first and second nanosheet portions; and a backside gate strap contact on a backside of the shared gate and on a backside of the DW, the backside gate strap contact in physical contact with lower surfaces of both the first and second shared gate portions of the shared gate, the first and second shared gate portions of the shared gate being electrically coupled to each other through the backside gate strap contact, wherein the first nanosheet portion forms a first channel when a first turn-on signal is applied to the shared gate and is prohibited from being formed when a second turn-on signal is applied to the shared gate, and wherein the second nanosheet portion forms a second channel when the second turn-on signal is applied to the shared gate and is prohibited from being formed when the first turn-on signal is applied to the shared gate.

Clause 2: The FS cell of clause 1, further comprising: a frontside metal on a frontside of the shared gate, the frontside metal in direct contact with an upper surface of the shared gate and configured to apply the first and second turn-on signals to the shared gate.

Clause 3: The FS cell of clause 2, further comprising: one or more frontside lines on the frontside of the shared gate above the frontside metal, at least one frontside line electrically coupled to an upper surface of the frontside metal and configured to provide the first and second turn-on signals to the frontside metal.

Clause 4: The FS cell of any of clauses 1-3, wherein a lower surface of the DW and the lower surface of the shared gate are aligned, and wherein an upper surface of the DW and an upper surface of the shared gate are aligned.

Clause 5: The FS cell of clause 4, wherein an upper surface of the backside gate strap contact is in contact with the lower surface of the shared gate and the lower surface of the DW.

Clause 6: The FS cell of any of clauses 1-5, further comprising: a first source/drain (S/D) and a second S/D both adjacent to the shared gate, the DW physically splitting the first S/D from the second S/D; and a backside passthrough contact on backsides of the first S/D, the second S/D, and the DW, the backside passthrough contact in physical contact with lower surfaces of both the first S/D and the second S/D, the first S/D and the second S/D being electrically coupled to each other through the backside passthrough contact, wherein when the first turn-on signal is applied to the shared gate, the first S/D is conductively coupled to the first channel of the first nanosheet portions of the plurality of nanosheets, and wherein when the second turn-on signal is applied to the shared gate, the second S/D is conductively coupled to the second channel of the second nanosheet portions of the plurality of nanosheets.

Clause 7: The FS cell of clause 6, further comprising: a frontside contact (FSC) on a frontside of the first S/D or on a frontside of the second S/D, the frontside contact in direct contact with an upper surface of the first S/D or an upper surface of the second S/D, the frontside contact configured to apply a signal, power or ground to the first and second S/Ds.

Clause 8: The FS cell of clause 7, further comprising: a frontside metal in contact with an upper surface of the frontside contact; and one or more frontside lines on the frontside of the first and second S/Ds above the frontside metal, at least one frontside line electrically coupled to an upper surface of the frontside metal and configured to provide the power, signal, or ground to the frontside metal.

Clause 9: The FS cell of any of clauses 6-8, wherein a lower surface of the DW and the lower surfaces of the first and second S/Ds are aligned, or wherein an upper surface of the DW is above upper surfaces of the first and second S/Ds, or both.

Clause 10: The FS cell of clause 9, wherein an upper surface of the backside passthrough contact is in contact with the lower surfaces of the first and second S/Ds and the lower surface of the DW.

Clause 11: The FS cell of any of clauses 6-10, wherein the lower surfaces of both the first S/D and the second S/D are above the lower surface of the shared gate, or wherein the lower surfaces of the DW is above the lower surface of the shared gate, or both.

Clause 12: The FS cell of any of clauses 1-11, further comprising: a first source/drain (S/D) and a second S/D both adjacent to the shared gate, the DW physically splitting the first S/D from the second S/D; a first direct backside contact (BSC) on a backside of the first S/D, the first direct BSC in physical contact with a lower surface the first S/D; and a second direct BSC on a backside of the second S/D, the second direct BSC in physical contact with a lower surface the second S/D, wherein when the first turn-on signal is applied to the shared gate, the first S/D is conductively coupled to the first channel of the first nanosheet portions of the plurality of nanosheets, and wherein when the second turn-on signal is applied to the shared gate, the second S/D is conductively coupled to the second channel of the second nanosheet portions of the plurality of nanosheets.

Clause 13: The FS cell of clause 12, further comprising: a first backside metal in contact with a lower surface of the first direct BSC, the first backside metal electrically coupled to the first S/D through the first direct BSC; and a second backside metal in contact with a lower surface of the second direct BSC, the second backside metal electrically coupled to the second S/D through the second direct BSC.

Clause 14: The FS cell of clause 13, further comprising: a first backside line in contact with the first backside metal, the first backside line providing a Vdd or a ground voltage to the first S/D through the first backside metal and the first direct BSC; or a second backside line in contact with the first backside metal, the second backside line providing the Vdd or the ground voltage to the second S/D through the second backside metal and the second direct BSC; or both.

Clause 15: The FS cell of any of clauses 12-14, wherein a lower surface of the DW is lower than the lower surfaces of the first and second S/Ds, or wherein an upper surface of the DW is above upper surfaces of the first and second S/Ds, or both.

Clause 16: The FS cell of any of clauses 12-15, wherein the lower surfaces of both the first S/D and the second S/D are above the lower surface of the shared gate, or wherein a lower surface of the DW is even with the lower surface of the shared gate, or both.

Clause 17: The FS cell of any of clauses 1-16, wherein the FS cell is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 18: A method of fabricating a forksheet (FS) cell, the method comprising: forming a shared gate; forming a plurality of nanosheets within the shared gate; forming a dielectric wall (DW) splitting the shared gate into first and second shared gate portions, the DW also splitting each nanosheet into first and second nanosheet portions; and forming a backside gate strap contact on a backside of the shared gate and on a backside of the DW, the backside gate strap contact in physical contact with lower surfaces of both the first and second shared gate portions of the shared gate, the first and second shared gate portions of the shared gate being electrically coupled to each other through the backside gate strap contact, wherein the first nanosheet portion forms a first channel when a first turn-on signal is applied to the shared gate and is prohibited from being formed when a second turn-on signal is applied to the shared gate, and wherein the second nanosheet portion forms a second channel when the second turn-on signal is applied to the shared gate and is prohibited from being formed when the first turn-on signal is applied to the shared gate.

Clause 19: The method of clause 18, further comprising: forming a frontside metal on a frontside of the shared gate, the frontside metal in direct contact with an upper surface of the shared gate and configured to apply the first and second turn-on signals to the shared gate.

Clause 20: The method of clause 19, further comprising: forming one or more frontside lines on the frontside of the shared gate above the frontside metal, at least one frontside line electrically coupled to an upper surface of the frontside metal and configured to provide the first and second turn-on signals to the frontside metal.

Clause 21: The method of any of clauses 18-20, wherein a lower surface of the DW and the lower surface of the shared gate are aligned, and wherein an upper surface of the DW and an upper surface of the shared gate are aligned.

Clause 22: The method of clause 21, wherein an upper surface of the backside gate strap contact is in contact with the lower surface of the shared gate and the lower surface of the DW.

Clause 23: The method of any of clauses 18-22, further comprising: forming a first source/drain (S/D) and a second S/D both adjacent to the shared gate, the DW physically splitting the first S/D from the second S/D; and forming a backside passthrough contact on backsides of the first S/D, the second S/D, and the DW, the backside passthrough contact in physical contact with lower surfaces of both the first S/D and the second S/D, the first S/D and the second S/D being electrically coupled to each other through the backside passthrough contact, wherein when the first turn-on signal is applied to the shared gate, the first S/D is conductively coupled to the first channel of the first nanosheet portions of the plurality of nanosheets, and wherein when the second turn-on signal is applied to the shared gate, the second S/D is conductively coupled to the second channel of the second nanosheet portions of the plurality of nanosheets.

Clause 24: The method of clause 23, further comprising: forming a frontside contact (FSC) on a frontside of the first S/D or on a frontside of the second S/D, the frontside contact in direct contact with an upper surface of the first S/D or an upper surface of the second S/D, the frontside contact configured to apply a signal, power or ground to the first and second S/Ds.

Clause 25: The method of clause 24, further comprising: forming a frontside metal in contact with an upper surface of the frontside contact; and forming one or more frontside lines on the frontside of the first and second S/Ds above the frontside metal, at least one frontside line electrically coupled to an upper surface of the frontside metal and configured to provide the power, signal, or ground to the frontside metal.

Clause 26: The method of any of clauses 23-25, wherein a lower surface of the DW and the lower surfaces of the first and second S/Ds are aligned, or wherein an upper surface of the DW is above upper surfaces of the first and second S/Ds, or both.

Clause 27: The method of clause 26, wherein an upper surface of the backside passthrough contact is in contact with the lower surfaces of the first and second S/Ds and the lower surface of the DW.

Clause 28: The method of any of clauses 23-27, wherein the lower surfaces of both the first S/D and the second S/D are above the lower surface of the shared gate, or wherein the lower surfaces of the DW is above the lower surface of the shared gate, or both.

Clause 29: The method of any of clauses 18-28, further comprising: forming a first source/drain (S/D) and a second S/D both adjacent to the shared gate, the DW physically splitting the first S/D from the second S/D; forming a first direct backside contact (BSC) on a backside of the first S/D, the first direct BSC in physical contact with a lower surface the first S/D; and forming a second direct BSC on a backside of the second S/D, the second direct BSC in physical contact with a lower surface the second S/D, wherein when the first turn-on signal is applied to the shared gate, the first S/D is conductively coupled to the first channel of the first nanosheet portions of the plurality of nanosheets, and wherein when the second turn-on signal is applied to the shared gate, the second S/D is conductively coupled to the second channel of the second nanosheet portions of the plurality of nanosheets.

Clause 30: The method of clause 29, further comprising: forming a first backside metal in contact with a lower surface of the first direct BSC, the first backside metal electrically coupled to the first S/D through the first direct BSC; and forming a second backside metal in contact with a lower surface of the second direct BSC, the second backside metal electrically coupled to the second S/D through the second direct BSC.

Clause 31: The method of clause 30, further comprising: forming a first backside line in contact with the first backside metal, the first backside line providing a Vdd or a ground voltage to the first S/D through the first backside metal and the first direct BSC; or forming a second backside line in contact with the first backside metal, the second backside line providing the Vdd or the ground voltage to the second S/D through the second backside metal and the second direct BSC; or both.

Clause 32: The method of any of clauses 29-31, wherein a lower surface of the DW is lower than the lower surfaces of the first and second S/Ds, or wherein an upper surface of the DW is above upper surfaces of the first and second S/Ds, or both.

Clause 33: The method of any of clauses 29-32, wherein the lower surfaces of both the first S/D and the second S/D are above the lower surface of the shared gate, or wherein a lower surface of the DW is even with the lower surface of the shared gate, or both.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals.

These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A forksheet (FS) cell, comprising:
a shared gate;
a plurality of nanosheets within the shared gate;
a dielectric wall (DW) splitting the shared gate into first and second shared gate portions, the DW also splitting each nanosheet into first and second nanosheet portions; and
a backside gate strap contact on a backside of the shared gate and on a backside of the DW, the backside gate strap contact in physical contact with lower surfaces of both the first and second shared gate portions of the shared gate, the first and second shared gate portions of the shared gate being electrically coupled to each other through the backside gate strap contact,
wherein the first nanosheet portion forms a first channel when a first turn-on signal is applied to the shared gate and is prohibited from being formed when a second turn-on signal is applied to the shared gate, and
wherein the second nanosheet portion forms a second channel when the second turn-on signal is applied to the shared gate and is prohibited from being formed when the first turn-on signal is applied to the shared gate.

2. The FS cell of claim 1, further comprising:
a frontside metal on a frontside of the shared gate, the frontside metal in direct contact with an upper surface of the shared gate and configured to apply the first and second turn-on signals to the shared gate.

3. The FS cell of claim 2, further comprising:
one or more frontside lines on the frontside of the shared gate above the frontside metal, at least one frontside line electrically coupled to an upper surface of the frontside metal and configured to provide the first and second turn-on signals to the frontside metal.

4. The FS cell of claim 1,
wherein a lower surface of the DW and the lower surface of the shared gate are aligned, and
wherein an upper surface of the DW and an upper surface of the shared gate are aligned.

5. The FS cell of claim 4, wherein an upper surface of the backside gate strap contact is in contact with the lower surface of the shared gate and the lower surface of the DW.

6. The FS cell of claim 1, further comprising:
a first source/drain (S/D) and a second S/D both adjacent to the shared gate, the DW physically splitting the first S/D from the second S/D; and
a backside passthrough contact on backsides of the first S/D, the second S/D, and the DW, the backside passthrough contact in physical contact with lower surfaces of both the first S/D and the second S/D, the first S/D and the second S/D being electrically coupled to each other through the backside passthrough contact,
wherein when the first turn-on signal is applied to the shared gate, the first S/D is conductively coupled to the first channel of the first nanosheet portions of the plurality of nanosheets, and
wherein when the second turn-on signal is applied to the shared gate, the second S/D is conductively coupled to the second channel of the second nanosheet portions of the plurality of nanosheets.

7. The FS cell of claim 6, further comprising:
a frontside contact (FSC) on a frontside of the first S/D or on a frontside of the second S/D, the frontside contact in direct contact with an upper surface of the first S/D or an upper surface of the second S/D, the frontside contact configured to apply a signal, power or ground to the first and second S/Ds.

8. The FS cell of claim 7, further comprising:
a frontside metal in contact with an upper surface of the frontside contact; and
one or more frontside lines on the frontside of the first and second S/Ds above the frontside metal, at least one frontside line electrically coupled to an upper surface of the frontside metal and configured to provide the power, signal, or ground to the frontside metal.

9. The FS cell of claim 6,
wherein a lower surface of the DW and the lower surfaces of the first and second S/Ds are aligned, or
wherein an upper surface of the DW is above upper surfaces of the first and second S/Ds, or
both.

10. The FS cell of claim 9, wherein an upper surface of the backside passthrough contact is in contact with the lower surfaces of the first and second S/Ds and the lower surface of the DW.

11. The FS cell of claim 6,
wherein the lower surfaces of both the first S/D and the second S/D are above the lower surface of the shared gate, or
wherein the lower surfaces of the DW is above the lower surface of the shared gate, or
both.

12. The FS cell of claim 1, further comprising:
a first source/drain (S/D) and a second S/D both adjacent to the shared gate, the DW physically splitting the first S/D from the second S/D;
a first direct backside contact (BSC) on a backside of the first S/D, the first direct BSC in physical contact with a lower surface the first S/D; and
a second direct BSC on a backside of the second S/D, the second direct BSC in physical contact with a lower surface the second S/D,
wherein when the first turn-on signal is applied to the shared gate, the first S/D is conductively coupled to the first channel of the first nanosheet portions of the plurality of nanosheets, and
wherein when the second turn-on signal is applied to the shared gate, the second S/D is conductively coupled to the second channel of the second nanosheet portions of the plurality of nanosheets.

13. The FS cell of claim 12, further comprising:
a first backside metal in contact with a lower surface of the first direct BSC, the first backside metal electrically coupled to the first S/D through the first direct BSC; and
a second backside metal in contact with a lower surface of the second direct BSC, the second backside metal electrically coupled to the second S/D through the second direct BSC.

14. The FS cell of claim 13, further comprising:
a first backside line in contact with the first backside metal, the first backside line providing a Vdd or a ground voltage to the first S/D through the first backside metal and the first direct BSC; or
a second backside line in contact with the first backside metal, the second backside line providing the Vdd or the ground voltage to the second S/D through the second backside metal and the second direct BSC; or
both.

15. The FS cell of claim 12,
wherein a lower surface of the DW is lower than the lower surfaces of the first and second S/Ds, or
wherein an upper surface of the DW is above upper surfaces of the first and second S/Ds, or
both.

16. The FS cell of claim 12,
wherein the lower surfaces of both the first S/D and the second S/D are above the lower surface of the shared gate, or
wherein a lower surface of the DW is even with the lower surface of the shared gate, or
both.

17. The FS cell of claim 1, wherein the FS cell is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

18. A method of fabricating a forksheet (FS) cell, the method comprising:
forming a shared gate;
forming a plurality of nanosheets within the shared gate;
forming a dielectric wall (DW) splitting the shared gate into first and second shared gate portions, the DW also splitting each nanosheet into first and second nanosheet portions; and
forming a backside gate strap contact on a backside of the shared gate and on a backside of the DW, the backside gate strap contact in physical contact with lower surfaces of both the first and second shared gate portions of the shared gate, the first and second shared gate portions of the shared gate being electrically coupled to each other through the backside gate strap contact,
wherein the first nanosheet portion forms a first channel when a first turn-on signal is applied to the shared gate and is prohibited from being formed when a second turn-on signal is applied to the shared gate, and
wherein the second nanosheet portion forms a second channel when the second turn-on signal is applied to the shared gate and is prohibited from being formed when the first turn-on signal is applied to the shared gate.

19. The method of claim 18, further comprising:
forming a frontside metal on a frontside of the shared gate, the frontside metal in direct contact with an upper surface of the shared gate and configured to apply the first and second turn-on signals to the shared gate; and
forming one or more frontside lines on the frontside of the shared gate above the frontside metal, at least one frontside line electrically coupled to an upper surface of the frontside metal and configured to provide the first and second turn-on signals to the frontside metal.

20. The method of claim 18,
wherein a lower surface of the DW and the lower surface of the shared gate are aligned, and
wherein an upper surface of the DW and an upper surface of the shared gate are aligned.

21. The method of claim 18, further comprising:
forming a first source/drain (S/D) and a second S/D both adjacent to the shared gate, the DW physically splitting the first S/D from the second S/D; and
forming a backside passthrough contact on backsides of the first S/D, the second S/D, and the DW, the backside passthrough contact in physical contact with lower surfaces of both the first S/D and the second S/D, the first S/D and the second S/D being electrically coupled to each other through the backside passthrough contact,
wherein when the first turn-on signal is applied to the shared gate, the first S/D is conductively coupled to the first channel of the first nanosheet portions of the plurality of nanosheets, and
wherein when the second turn-on signal is applied to the shared gate, the second S/D is conductively coupled to the second channel of the second nanosheet portions of the plurality of nanosheets.

22. The method of claim 21, further comprising:
forming a frontside contact (FSC) on a frontside of the first S/D or on a frontside of the second S/D, the frontside contact in direct contact with an upper surface of the first S/D or an upper surface of the second S/D, the frontside contact configured to apply a signal, power or ground to the first and second S/Ds.

23. The method of claim 22, further comprising:
forming a frontside metal in contact with an upper surface of the frontside contact; and
forming one or more frontside lines on the frontside of the first and second S/Ds above the frontside metal, at least one frontside line electrically coupled to an upper surface of the frontside metal and configured to provide the power, signal, or ground to the frontside metal.

24. The method of claim 21,
wherein a lower surface of the DW and the lower surfaces of the first and second S/Ds are aligned, or
wherein an upper surface of the DW is above upper surfaces of the first and second S/Ds, or
both.

25. The method of claim 21,
wherein the lower surfaces of both the first S/D and the second S/D are above the lower surface of the shared gate, or
wherein the lower surfaces of the DW is above the lower surface of the shared gate, or
both.

26. The method of claim 18, further comprising:
forming a first source/drain (S/D) and a second S/D both adjacent to the shared gate, the DW physically splitting the first S/D from the second S/D;
forming a first direct backside contact (BSC) on a backside of the first S/D, the first direct BSC in physical contact with a lower surface the first S/D; and
forming a second direct BSC on a backside of the second S/D, the second direct BSC in physical contact with a lower surface the second S/D,
wherein when the first turn-on signal is applied to the shared gate, the first S/D is conductively coupled to the first channel of the first nanosheet portions of the plurality of nanosheets, and
wherein when the second turn-on signal is applied to the shared gate, the second S/D is conductively coupled to the second channel of the second nanosheet portions of the plurality of nanosheets.

27. The method of claim 26, further comprising:
forming a first backside metal in contact with a lower surface of the first direct BSC, the first backside metal electrically coupled to the first S/D through the first direct BSC; and
forming a second backside metal in contact with a lower surface of the second direct BSC, the second backside metal electrically coupled to the second S/D through the second direct BSC.

28. The method of claim 27, further comprising:
forming a first backside line in contact with the first backside metal, the first backside line providing a Vdd or a ground voltage to the first S/D through the first backside metal and the first direct BSC; or
forming a second backside line in contact with the first backside metal, the second backside line providing the Vdd or the ground voltage to the second S/D through the second backside metal and the second direct BSC; or
both.

29. The method of claim 26,
wherein a lower surface of the DW is lower than the lower surfaces of the first and second S/Ds, or
wherein an upper surface of the DW is above upper surfaces of the first and second S/Ds, or
both.

30. The method of claim 26,
wherein the lower surfaces of both the first S/D and the second S/D are above the lower surface of the shared gate, or
wherein a lower surface of the DW is even with the lower surface of the shared gate, or
both.
